(19) United States
(12) Patent Application Publication
(10) Pub. No.: US 2014/0218023 A1
(43) Pub. Date: Aug. 7, 2014

(54) NMR FLOWMETER WITH SUPERCONDUCTING POLARIZER

(71) Applicant: Edmund Fordham, Cambridge (GB)

(72) Inventor: Edmund Fordham, Cambridge (GB)

(73) Assignee: SCHLUMBERGER TECHNOLOGY CORPORATION, SUGAR LAND, TX (US)

(21) Appl. No.: 14/238,833

(22) PCT Filed: Aug. 12, 2012
(86) PCT No.: PCT/IB2012/054181

§ 371 Date: Feb. 13, 2014

(30) Foreign Application Priority Data
Aug. 17, 2011 (GB) 1114159.5

(51) Int. Cl. G01F 1/56; G01R 33/44

(52) U.S. Cl. CPC G01F 1/56; G01R 33/44
USPC 324/306

(57) ABSTRACT

A fluid flowmeter which uses nuclear magnetic resonance to determine quantities of flowing fluid(s) has a polarizing magnet system with magnets which are high temperature superconductors such as yttrium barium copper oxide (YBCO) or bismuth strontium calcium copper oxide (BSCCO) which are superconducting at liquid nitrogen temperature and provide a greater magnetic field strength than conventional magnets. This may allow the flowmeter to accept higher through flow rate and/or may allow observation of ²³Na in an aqueous phase as well as ¹H.

### BACKGROUND OF THE INVENTION

There are various methods for measuring parameters of flow of fluid produced from an underground wellbore. One possibility is nuclear magnetic resonance (NMR) which is sometimes referred to merely as magnetic resonance and which potentially has ability to discriminate between different phases of multi-phase flow, measure the quantity of flowing fluid and also measure the motion of the fluid. Use of NMR for flow measuring/monitoring has been known for a number of years. It was disclosed in U.S. Pat. Nos. 3,191,119 and 3,419,715 and has been the subject of other patents since then, including U.S. Pat. Nos. 6,046,587, 7,501,819, 7,852,074 and 7,872,474. In order to observe magnetic resonance, such apparatus has a magnet system and one or more radio frequency coils located within the field of the magnet system which induce and observe magnetic resonance within the flow of fluid as it passes through the field of the magnet system.

While it is possible to utilize a single radio frequency coil in a single magnetic field, there have been proposals (U.S. Pat. No. 5,684,399 and also U.S. Pat. No. 6,046,587) to provide two or more radio frequency coils spaced axially in the direction of fluid flow, so that fluid flows through them in succession and time of travel between them can be measured. The coils may then lie within a single magnetic field or there may be a separate magnet system associated with each coil.

Generally, an NMR flowmeter will include a polarizing magnet system to provide a polarizing magnetic field positioned upstream of the magnetic field in which resonance takes place. Such a flowmeter can be considered to have a polarizing section with a magnet system, upstream of a resonance section with a magnet system and radiofrequency coil(s). The purpose of the polarizing magnetic field is to orient the spins of the relevant nuclei in the fluid before it enters the resonance section. The polarizing magnetic field alters the distribution of spin directions from natural equilibrium towards a saturated state in which all spins would be oriented in the same direction.

A polarizing magnet system and also the magnet system of the resonance section have typically been provided by permanent magnets which are ferromagnetic at ambient temperature. Such magnets include neodymium-iron-boron (NdFeB) magnets which give a higher magnetic field than more traditional iron permanent magnets. Permanent magnets which are ferromagnetic at ambient temperature will be referred to herein as ‘conventional’ permanent magnets.

NMR flowmeter apparatus such as described in the documents above has the attraction that it does not require any parts to be placed within the pipeline carrying the flow to be measured. It may be used for measuring the volume of flow. In some prior documents the apparatus is intended to measure a multiphase flow and determine the flow rates and proportions of the individual phases present in the flow (typically oil, gas and an aqueous phase). The nucleus whose magnetic resonance is observed has been ¹H. It is of course abundant in both water and hydrocarbon oil.

### SUMMARY OF THE INVENTION

This invention provides a fluid flowmeter with (i) a magnetic resonance section which has at least one magnet system to subject the flowing fluid to a magnetic field and at least one radio frequency coil to observe magnetic resonance of nuclei in the flowing fluid and (ii) a polarizing magnet system positioned to subject the flowing fluid upstream of the resonance section to a polarizing magnet field
characterized in that the polarizing magnet system comprises one or more superconducting magnets.

The magnitude of polarization achieved during passage through a polarizing magnet is dependent on the strength of the magnetic field and the residence time within that field. Superconducting magnets can provide a magnetic field strength which is much higher than the field strengths provided by conventional permanent magnets. Because of their higher field strength they can bring about greater polarization of spins than a conventional polarizing magnet system when the residence time is the same. Greater polarization could lead to a better signal-to-noise ratio and a higher quality of measurement. However, for observing magnetic resonance of ¹H nuclei this improved ratio of polarization to residence time may be utilised to allow a higher fluid flow rate through the polarizing magnet thus increasing the capacity of the flowmeter without demanding a corresponding increase in size of the polarizing magnet. Thus, a flowmeter can be used at higher fluid flow rates without the considerable increase in size and weight which would be required if a polarizer based on conventional permanent magnets were to be used at such fluid flow rates.

It would lie within the scope of this invention to employ superconducting magnets to provide magnetic field in both the polarizing and resonance sections. However, it may be more convenient to employ one or more conventional permanent magnets to provide the magnetic field in the resonance section. Indeed, the resonance section may be of one of the known designs, including those with more than one radio frequency coil spaced axially, and so some embodiments of this invention can be regarded as replacing the conventional polarizing section of a known NMR flowmeter with a polarizing section which has superconducting magnets in accordance with this invention, thereby increasing the capacity of the known flowmeter.

### BRIEF DESCRIPTION OF THE DRAWINGS

FIG. 1 schematically illustrates a flowmeter;

FIG. 2 is a schematic graph of polarization against residence time to illustrate the polarization of ¹H spins by polarizing magnets of different strength;

FIG. 3 is a similar graph, also including ²³Na.

### DETAILED DESCRIPTION

Superconducting magnets fall into two categories. The first superconducting magnets required cooling down to extremely low temperatures and liquid helium was normally used as coolant to achieve cooling down to 4° K. At this very low temperature some materials are superconducting and are used as electric conductors to allow electric current to flow indefinitely in a superconducting coil.

More recently, so-called high-temperature superconducting magnets have become available. These are formed of a material which displays superconductivity at temperatures which are far below ambient but extend up to, and somewhat above, the boiling temperature of liquid nitrogen which is 77K=−196° C. Magnetization causes induced current to flow in the material. Because the material is superconducting, the induced current continues to flow indefinitely and the magnetic field persists indefinitely so long as temperature remains cold enough. These materials can be magnetized while in the form of solid blocks and they then behave as though they were permanent magnets, but more powerful than conventional permanent magnets. Consequently, these high-temperature superconductors are sometimes referred to as bulk or block superconductors.

In some embodiments of this invention these high-temperature superconducting block magnets are used to provide the polarizing magnet system. They have geometry which is different from that of a superconducting coil so that they can readily provide a magnetic field transverse to the direction of fluid flow and also the advantage (relative to the first category of superconductors) that cooling to approximately liquid nitrogen temperature is sufficient.

Known materials in this category include cuprate ceramics. The first of these was yttrium barium copper oxide (YBCO). Other rare earth elements can be used in place of yttrium. Another material which is superconducting above 77K is bismuth strontium calcium copper oxide (BSCCO). The literature concerning these high temperature superconductors is extensive. One example of literature describing techniques for the preparation of these superconducting materials in block form is “Chemistry of Superconducting Materials” edited T. A. Vanderah, Noyes Publications 1992. Manufacture of YBCO has also been discussed by Meng et al, Nature vol 345 pp 326-8 (1990). Further papers on preparation include Vandewalle, Supercond. Sci. Technol. Vol 11, pages 35-43; Reddy et al, Supercond. Sci. Technol. Vol 11, pages 523-534 (1998) and Cloots et al, Supercond. Sci. Technol. Vol 18, pages R9-R23 (2007).

The flowmeter will incorporate provision for cooling the magnets to superconducting temperature and this will generally use liquefied gas as the coolant. In one possible arrangement, the superconducting magnets will be enclosed, together with liquefied gas, in a vessel with double walls separated by an evacuated space, commonly known as a Dewar vessel or vacuum flask. In areas where liquid nitrogen is commercially available and can be delivered by a road vehicle, it is likely that liquid nitrogen will be used. In remote areas it may be necessary to manufacture the liquefied gas on site by liquefaction of air, in which case the coolant may be a liquefied gas mixture which is predominantly nitrogen but retains some oxygen content.

So-called high temperature superconducting magnets must generally be magnetized after they have been cooled to a temperature at which they have the superconducting property.

Some methods of magnetizing a superconducting material require that it is exposed to a magnetic field having a field strength which is at least as great as the field which it is desired to impart to the superconducting magnet. This may be impractical when a high magnetic field is desired.

Another method is flux pumping, in which a magnetic field is repeatedly applied to a superconductor in such a way that each application of magnetic field induces additional current to flow, thereby reinforcing current which is already flowing. This increases the current which continues to circulate indefinitely within the superconductor and thereby increases the magnetic field.

This process is sometimes described as ‘capture’ or ‘trapping’ of magnetic field by the superconductor. It is a convenient description of the observation that the magnetic field of the superconductor increases through exposure to another magnetic field, although the reality is that this exposure to a magnetic field induces additional current in the superconductor, as explained above.

One method of flux pumping involves repeatedly moving a magnet across a superconductor, with the magnetic field of the moving magnet extending at right angles to the surface of the superconductor. Another possibility is to generate a moving magnetic field by energizing a number of solenoid coils in sequence. With both of these approaches, provided the path of the magnetic field is the same each time it passes across the superconductor, each pass of the magnetic field induces more current to flow in the same sense, and the magnetic field of the superconductor will increase.

Flux pumping cannot be continued indefinitely so as to lead to an infinite magnetic field: eventually the magnetic field will exceed a critical value which the superconducting material cannot sustain. It is also possible that internal forces within a block of the superconducting material can become large enough to cause it to break. Nevertheless flux pumping can lead to a superconducting magnet which has a very high magnetic field, of greater strength than can be achieved with a conventional ferromagnetic permanent magnet. A review of flux pumping was given by van de Klundert and ten Kate in Cryogenics volume 21 pages 196-206 (1981).

More recently a new method of flux pumping of high-temperature superconductors has been disclosed in W02007/045929 and in Coombs et al, Superconductor Sci. & Tech. Volume 21, article 034001 (2008). This approach employs a material with magnetic properties which undergo a transition when temperature of the material crosses a certain value. This temperature-sensitive material is positioned adjacent a block of superconducting material so that a magnetic field coming from or through the temperature sensitive material can induce current in the superconductor. Repeated pulses of the heat supplied by a heating coil are made to travel through the temperature sensitive material, temporarily lifting its temperature through the point at which there is a transition in magnetic properties. Each moving pulse of heat provides a moving pulse of changed magnetic properties which consequently subjects the superconductor to a moving magnetic field. The result is that the application of repeated pulses of heat to the temperature sensitive material leads to progressive increase in the magnetization of the superconductor.

One possibility is that the thermal transition of the material changes the amount of the Earth's magnetic field passing through the temperature sensitive material and adjacent superconductor. Alternatively, the temperature-sensitive material may be positioned between the superconductor and a permanent magnet so that the temperature-sensitive transition in magnetic properties of this material changes the amount of magnetic flux reaching the superconductor from the permanent magnet. It is also possible to employ a temperature sensitive material which itself becomes magnetic as its temperature crosses the boundary value. Means for flux pumping the superconducting magnet system may be built in to the polarizing section of a flowmeter embodying this invention.

The Resonance Section

The resonance section of the flowmeter is used to observe magnetic resonance in the flowing fluid. In many embodiments of this invention it also induces the magnetic resonance which is observed. It may be of known construction. It comprises at least one magnet system to provide a static magnetic field and least one radio-frequency coil. A radio-frequency coil may take the form of a solenoid ecircling the flowing fluid although other possibilities exist.

The magnet system to provide the static magnetic field in the resonance section may, if desired, comprise one or more superconducting magnets. These would provide a very strong magnetic field which at first sight appears desirable. However, because it is normally required that the static field in the resonance section is of uniform strength, or of uniform strength with a superimposed field gradient, whereas this requirement for uniformity of field strength does not apply to a polarizing magnet system whose function is to polarize spins before magnetic resonance is induced and observed, it may be convenient to rely on conventional technology for the magnet system of the resonance section while utilizing high temperature block superconductors for the polarizing magnet system.

The main magnetic field in the resonance section could be provided by one or more electromagnets, although it may be more convenient that the magnet system includes at least one ferromagnetic permanent magnet. A pair of permanent magnets mounted facing each other may be used to provide a magnetic field in a space between them. Another possibility is to use pole pieces which carry magnetic flux from a single permanent magnet or from an electromagnet.

In some embodiments, the magnet system of the resonance section provides a uniform magnetic field. In other embodiments the magnet system is constructed to have a magnetic field gradient superimposed on a uniform static magnetic field.

A magnetic field gradient can be provided by shaping of the magnetic poles, for example by using a pair of magnets which vary in thickness or in spacing between them, so as to produce a gradient in the strength of magnetic field between them. Another possibility is that a magnetic field gradient may be provided by means of one or more gradient coils (usually a pair) which superimpose a field gradient onto a uniform magnetic field such as may be provided by a pair of permanent magnets. Gradient coils can be operated to produce a fixed magnetic field gradient but they can also be operated with variation of the current in the coils so as to produce a field gradient of varying magnitude. In particular gradient coils may be operated to vary the magnetic field in repeated pulses as required by some NMR techniques.

NMR Techniques

The magnetic resonance observed by the resonance section may be ¹H NMR and may use a procedure which is already known for a flowmeter with a polarizing magnetic field. A considerable number of NMR procedures are known and are described in standard textbooks such as P. T. Callaghan: “Principles of Nuclear Magnetic Resonance Microscopy” and R Kimmich “NMR: Tomography, Diffusometry & Relaxometry”.

The NMR procedure may entail subjecting the flowing fluid to sequences of pulses and it may lead to determination of one or more parameters selected from transverse relaxation time, T₂, longitudinal relaxation time, T₁, and diffusion coefficient, D.

The value of one or more of these parameters, or a ratio of two of them, may be characteristic of liquid hydrocarbon, gaseous hydrocarbon or aqueous solution. The NMR procedure may determine signal amplitude correlated with one or more of the above parameters in order to give measurements of the amounts of liquid hydrocarbon, gaseous hydrocarbon and aqueous phase currently within the resonance section.

Turning now to the drawings, FIG. 1 illustrates the component parts of the flowmeter. The polarizing section is to the left of line X-X and the resonance section is to the right of that line. Liquid flow denoted by arrow 10 travels along a non-magnetic flow pipe which contains and directs the flow of fluid through the flowmeter. The pipe 14 passes through a polarizing magnet system 16, 18 having a length L before entering the resonance section which has a magnet system 20, 22 to provide a uniform static magnetic field, gradient coils 24 to superimpose a field gradient on the uniform field and a radio-frequency coil 26 to apply radiofrequency pulses and observe radiofrequency emissions from the flow through the resonance section. The magnets 20, 22 at each side of the pipe 14 are neodymium-iron-boron (NdFeB) permanent magnets. An electronics package for operating gradient coils 24 and radio-frequency coil 26 is schematically indicated at 28. If desired, there could be more than one radiofrequency coil, for example one coil to transmit radiofrequency pulses and another coil within it to receive radiofrequency emissions or two radio-frequency coils spaced axially in the direction of fluid flow

The polarizing magnet system consists of a pair of magnet assemblies 16, 18 each of which is composed of a number of blocks of high-temperature superconducting material which have been magnetized to a field strength which is greater than can be provided by conventional permanent magnets. These assemblies are located within a double walled enclosure 30 formed of non-magnetic material and filled with liquid nitrogen to maintain the magnet assemblies 16, 18 at −196° C.

Means are provided for magnetizing the superconducting magnets assemblies 16, 18 after they have been cooled to the temperature of liquid nitrogen within the enclosure 30. This is done in a manner taught by WO2007/045929 the disclosure of which is incorporated herein by reference.

Each of the magnet assemblies 16, 18 has a NdFeB permanent magnet 32 placed alongside it with a block 34 of another material sandwiched between the magnet 32 and the magnet assembly 16 or 18. This block 34 is formed of a material which undergoes a change in magnetic properties on heating somewhat above the temperature of liquid nitrogen, for instance Prussian Blue as discussed in WO2007/045929.

When it is required to magnetize the assemblies 16, 18 after cooling to the temperature of liquid nitrogen, heaters 36 at the ends of the blocks 34 are operated intermittently. This causes pulses of raised temperature to travel along the blocks 34 and because the material of the blocks 34 changes its magnetic properties when heated, the magnet assembly 16 or 18 experiences a pulse of changed exposure to magnetic field from the magnet 32.

Thus, repeated operation of the heaters 36 subjects the assemblies 16, 18 to repeated travelling pulses of changed magnetic field which progressively magnetizes the assemblies 16, 18 by the flux pumping phenomenon described in WO2007/045929. After the assemblies 16, 18 have been magnetized they remain magnetized indefinitely, so long as the liquid nitrogen cooling is maintained. The heaters 36 are not used again unless and until re-magnetization is required.

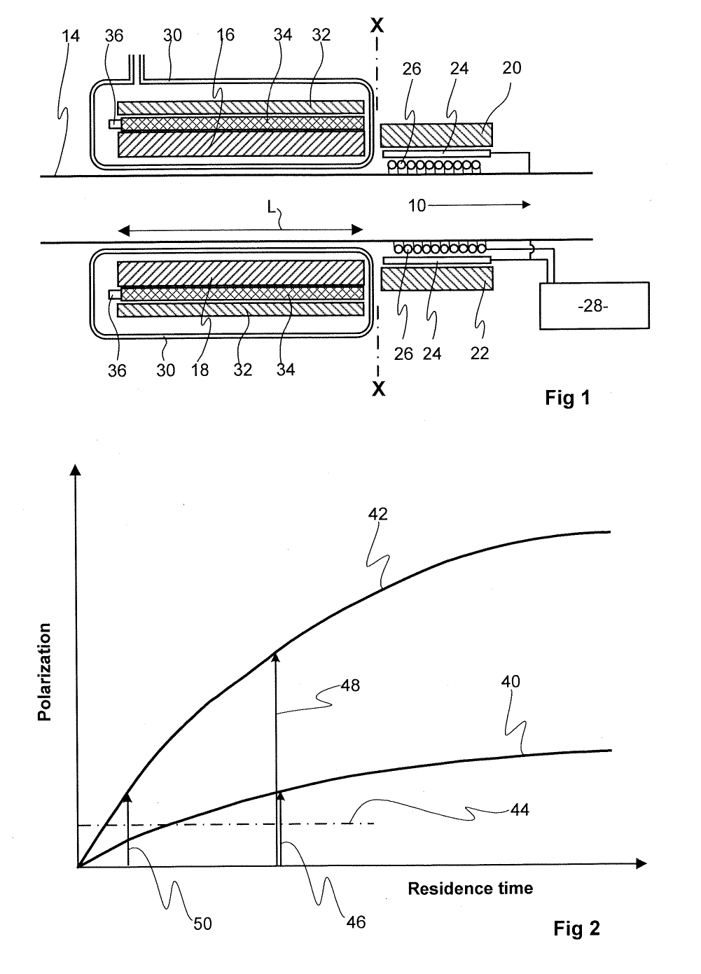

During operation of the flowmeter the heaters 36 are not operated. The flowing fluid in the pipe 14 is subjected to the polarizing magnetic field provided by the superconducting magnet system 16, 18 before it enters the resonance section. The advantage of using superconducting magnet assemblies to provide a high field will now be pointed out, referring to FIG. 2 which is a schematic graph which illustrates polarization against residence time. The lower curve 40 shows the extent of polarization against time by conventional ferromagnetic permanent magnets while the upper curve 42 shows polarization by high-temperature superconducting magnet system giving a field strength approximately three times greater so that a higher magnitude of polarization is achievable. The line 44 denotes the minimum magnitude of polarization required to observe ¹H resonance with an acceptable signal-to-noise ratio. With a conventional ferromagnetic polarizing magnet system the length L of the polarizing magnet system would be chosen in relation to the liquid flow rate so that the residence time and extent of polarization would be at the position indicated by arrow 46. It will be seen that the magnitude of polarization achieved in this residence time is not as great as could be achieved with a longer residence time but is above the minimum indicated by line 44.

A threefold increase in the strength of the polarizing magnetic field would allow a considerable increase in the magnitude of polarization while keeping the residence time unchanged as is indicated by arrow 48.

However, an alternative using the superconducting magnet system in accordance with an embodiment of this invention is to raise the flow rate and so reduce the residence time so that the residence time and extent of polarization are as indicated by arrow 50. It will be seen that the magnitude of polarization is then approximately the same as indicated by arrow 46 but the residence time is greatly reduced. Thus the flow rate can be increased without requiring a larger polarizing magnet system of greater length.

Heteronuclei

Many nuclei other than ¹H have magnetic spin. However, they give weaker resonance signals than ¹H and so are harder to observe. In some embodiments of this invention the resonance section of the flowmeter may used to observe both ¹H resonance and magnetic resonance of another nucleus. The high field strength of a polarizing magnetic field provided by a superconducting magnet system may serve to make this possible because it increases the polarization of nuclear spins and thereby improves the signal-to-noise ratio from the second nucleus as well as from ¹H.

In some forms of this invention, the nuclei which are monitored by NMR are ¹H and ²³Na. Sodium will not be present in the hydrocarbon phase but is very likely to be present as part of the salinity in an aqueous phase mixed with hydrocarbon. Observing ²³Na resonance will allow observation of the aqueous phase in a multiphase flow containing both an oil phase and an aqueous phase. More specifically, monitoring amplitudes of ²³Na resonance and ¹H resonance and determining their ratio will measure the proportion of saline aqueous phase in the mixed flow. It will be necessary to know the concentration of sodium ions in the saline aqueous phase but when this is being produced from an underground reservoir the content of dissolved salt(s) will not change rapidly and can be determined periodically by analysis of a sample of the aqueous phase.

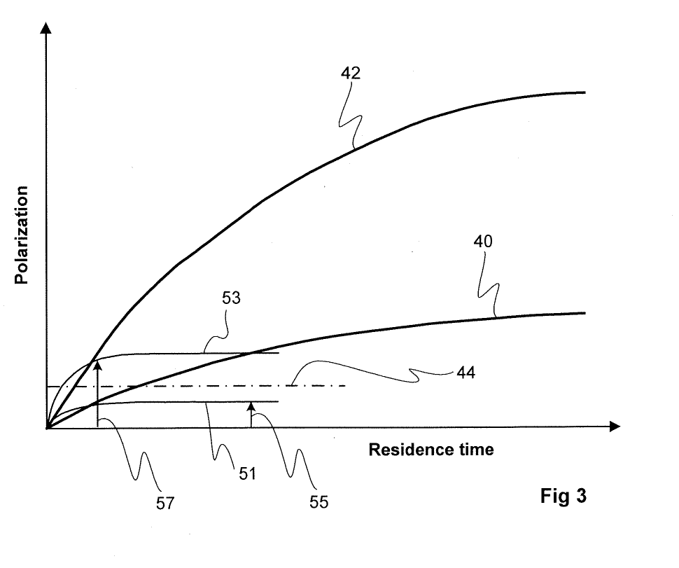

The inventors have recognized that using an increased polarizing magnetic field will increase the polarization of ²³Na relative to the polarization of ¹H, thereby improving the signal to noise ratio of signals from ²³Na which are weaker than those from ¹H and assisting the observation of ²³Na as well as ¹H. This is illustrated by FIG. 3 which is a schematic graph similar to FIG. 2 but including additional curves 51 and 53 which show the polarization of ²³Na.

The polarization of ²³Na is much faster than polarization of ¹H and so the polarization achieved during the residence time in the polarizing magnetic field may approach the maximum achievable, even if a conventional magnet system is used to provide the polarizing field. However, with a conventional magnet system the extent of polarization which is reached, indicated by arrow 55 comes below the minimum 44 for detection. With a superconducting magnet system, the extent of polarization is greater, even with a shorter residence time, as indicated at 57 and is sufficient that ²³Na is detectable.

1. A flowmeter for fluid comprising:
a duct to contain and direct fluid flow through the flowmeter
a resonance section having at least one magnet system to subject the flowing fluid to a magnetic field and at least one radio frequency coil to observe magnetic resonance of nuclei in the flowing fluid; and
a polarizing magnet system positioned to subject fluid upstream of the resonance section to a polarizing magnetic field,
characterized in that the polarizing magnet system comprises one or more superconducting magnets and the flowmeter comprises means for cooling the magnets to a working temperature at which those magnets are superconducting.

2. A flowmeter according to claim 1 wherein the superconducting magnets are superconducting up to a temperature above the boiling temperature of liquid nitrogen.

3. A flowmeter according to claim 1 wherein the superconducting magnets are formed from a cuprate ceramic.

4. A flowmeter according to claim 3 wherein the superconducting magnets are formed from yttrium barium copper oxide (YBCO) or bismuth strontium calcium copper oxide (BSCCO).

5. A flowmeter according to claim 1 wherein the polarizing magnet system comprises means for progressively magnetizing the superconducting magnets by flux pumping.

6. A flowmeter according to claim 1 wherein the resonance section is configured to observe resonance of both ¹H and ²³Na.

7. A method of measuring fluid flow comprising passing the flow of fluid through a polarizing magnetic field followed by passing it through a resonance section having a magnet system to subject the flowing fluid to a magnetic field and at least one radio frequency coil to observe magnetic resonance of nuclei in the flowing fluid;
wherein the polarizing magnetic field is provided by a polarizing magnet system which comprises one or more superconducting magnets.

8. A method according to claim 7 wherein the fluid flow is a mixture of hydrocarbon oil and aqueous solution.

9. A method according to claim 7 wherein the fluid flow includes a gas phase.

10. A method according to claim 7 including cooling the polarizing magnet system with liquid nitrogen, wherein the superconducting magnets are superconducting up to a temperature above the boiling temperature of liquid nitrogen.

11. A method according to claim 7 including progressively magnetizing the superconducting magnets of the polarizing magnet system by flux pumping.

12. A method according to claim 7 including observing resonance of both 1H and 23Na.
